(19) United States
(12) Patent Application Publication
(10) Pub. No.: US 2025/0026912 A1
(43) Pub. Date: Jan. 23, 2025

(54) LIQUID COMPOSITION, PREPREG, METAL SUBSTRATE WITH RESIN, AND WIRING BOARD

(71) Applicants: AGC INC., Tokyo (JP); AGC SI-TECH CO., LTD., Kitakyushu-shi (JP)

(72) Inventor: Hiromichi KAMO, Chiyoda-ku (JP)

(73) Assignees: AGC INC., Tokyo (JP); AGC SI-TECH CO., LTD., Kitakyushu-shi (JP)

(21) Appl. No.: 18/909,141

(22) Filed: Oct. 8, 2024

Related U.S. Application Data
(63) Continuation of application No. PCT/JP2023/014001, filed on Apr. 4, 2023.

(30) Foreign Application Priority Data
Apr. 12, 2022 (JP) 2022-065666

(51) Int. Cl. C08K 3/36; C08J 5/24; C08L 71/12; H05K 1/03

(52) U.S. Cl. CPC C08K 3/36; C08J 5/249; C08L 71/12; H05K 1/0373; C08K 2201/003

(57) ABSTRACT

A liquid composition containing a thermosetting resin, first silica particles, second silica particles, and a solvent, in which the first silica particles have a median diameter d50 of from 1.5 μm to 20.0 μm, the product of a specific surface area and the median diameter d50 being from 2.7 to 5.0 μm m²/g, and the second silica particles have a median diameter d50 of from 0.3 μm to less than 1.5 μm; and a prepreg, a metal substrate with a resin, and a wiring board using the same are provided.

### CROSS-REFERENCE TO RELATED APPLICATION

This application is a Continuation of International Application No. PCT/JP2023/014001, filed on Apr. 4, 2023, which claims priority to Japanese Patent Application No. 2022-065666, filed on Apr. 12, 2022. Each of the above applications is hereby expressly incorporated by reference, in its entirety, into the present application.

### TECHNICAL FIELD

The present disclosure relates to a liquid composition, a prepreg, a metal substrate with a resin, and a wiring board.

### BACKGROUND ART

Liquid compositions containing thermosetting resin and silica particles are used to manufacture electrically insulating layers provided in metal-clad laminates that can be processed into printed wiring boards (see Patent Literatures 1 and 2). Specifically, metal-clad laminates in which a semi-cured product of a liquid composition is layered on the surface of a metal substrate layer as an electrically insulating layer, and metal-clad laminates in which a glass cloth or the like impregnated with the liquid composition is layered on the surface of a metal substrate layer as an electrically insulating layer, are used. In recent years, there has been a demand for electrically insulating layers of printed wiring boards to have improved properties such as a low dielectric constant, a low dielectric tangent, and a low linear expansion coefficient.

### CITATION LIST

### Patent Literature

Patent Literature 1: JP 2013-212956 A
Patent Literature 2: JP 2015-036357 A

### SUMMARY OF INVENTION

### Technical Problem

In a liquid composition containing a thermosetting resin and silica particles, there are cases in which the amount of silica particles added is increased in order to achieve a high filling rate, from the viewpoint of improving the low-dielectric properties, resistance to high temperature and high humidity, and the like, of the shaped material formed from the liquid composition. In this case, however, the wettability of the silica particles by the liquid composition is decreased, and the silica particles become more likely to aggregate, which may cause generation of voids during the shaping process and decrease in the insulation properties, strength, and moisture resistance. Furthermore, the aggregation of silica particles may cause an increase in the surface roughness of the shaped material, resulting in reduced adhesion to the substrate.

Given the foregoing circumstances, the present disclosure is directed to providing a liquid composition capable of suppressing the aggregation of silica particles, as well as a prepreg, a metal substrate with a resin, and a wiring board using the liquid composition.

### Solution to Problem

The solution to the above-described problem includes the following aspects.

(1) A liquid composition, containing:
a thermosetting resin;
first silica particles;
second silica particles; and
a solvent, wherein:
the first silica particles have a median diameter d50 of from 1.5 μm to 20.0 μm, a product of a specific surface area and the median diameter d50 being from 2.7 to 5.0 μm m² and
the second silica particles have a median diameter d50 of from 0.3 μm to less than 1.5 μm.
   (2) The liquid composition according to (1), wherein a total content of silica particles is from 10% to 90% by mass based on a total solid content of the liquid composition.
   (3) The liquid composition according to (1) or (2), wherein a mass ratio of the first silica particles to the second silica particles (first silica particles/second silica particles) is from 0.1 to 10.0.
   (4) The liquid composition according to any one of (1) to (3), wherein the median diameter d50 of the first silica particles is in a range of from 2.0 to 8.0 times larger than the median diameter d50 of the second silica particles.
   (5) The liquid composition according to any one of (1) to (4), wherein the first silica particles have a specific surface area of from 0.1 to 3.5 m²/g.
   (6) The liquid composition according to any one of (1) to (5), wherein the first silica particles have a median diameter d50 of from 1.5 μm to 5.0 μm.
   (7) The liquid composition according to any one of (1) to (6), wherein silica particles in the liquid composition exhibit a bimodal particle size distribution as measured by a laser diffraction/scattering method.
   (8) The liquid composition according to any one of (1) to (7), wherein the thermosetting resin is an epoxy resin, a polyphenylene ether resin, or an ortho-divinylbenzene resin.
   (9) The liquid composition according to any one of (1) to (8), wherein the solvent includes at least one selected from the group consisting of toluene, cyclohexanone, methyl ethyl ketone, and N-methyl-2-pyrrolidone.
   (10) A prepreg, including:
the liquid composition according to any one of (1) to (9) or a semi-cured product thereof; and
a fibrous substrate.
   (11) A metal substrate with a resin including:
the liquid composition according to any one of (1) to (9) or a semi-cured product thereof, or the prepreg according to (10); and
a metal substrate layer.
   (12) The metal substrate with a resin according to (11), wherein the metal substrate layer is copper foil.
   (13) The metal substrate with a resin according to (12), wherein the copper foil has a maximum height roughness Rz of 2 μm or less.
   (14) A wiring board, including:
a cured product of the liquid composition according to any one of (1) to (9); and
a metal wiring.

### Advantageous Effects of Invention

According to the present disclosure, a liquid composition capable of suppressing the aggregation of silica particles, as well as a prepreg, a metal substrate with a resin, and a wiring board using the liquid composition are provided.

### DESCRIPTION OF EMBODIMENTS

Hereinafter, embodiments of the present disclosure will be described in detail. However, embodiments of the present disclosure are not limited to the following embodiments. Components (including element steps and the like) in the following embodiments are not essential unless otherwise specified. The same applies to numerical values and their ranges, and the numerical values and their ranges do not limit the embodiments of the present disclosure.

In the present disclosure, numerical ranges indicated using “to” includes the numerical values described before and after “to” as the minimum value and the maximum value, respectively.

In the present disclosure, each component may contain plural kinds of corresponding substances. In a case in which plural kinds of substances corresponding to a component are present in the composition, the content or amount of the component means the total content or amount of the plural kinds of substances present in the composition unless otherwise specified.

In the present disclosure, plural kinds of particles corresponding to a component may be contained. When plural kinds of particles corresponding to a component are present in a composition, the particle diameter of the component means a value for the mixture of the plural kinds of particles present in the composition unless otherwise specified.

In the present disclosure, “silica particles” refers to a group of silica particles unless otherwise specified.

In the present disclosure, the “median diameter d50” (hereinafter, also simply referred to as “d50”) is a volume-based cumulative 50% diameter of the particles determined using a laser diffraction particle size distribution measuring device (e.g., “MT3300EXII” manufactured by MicrotracBEL Corp.). In other words, it is a particle diameter at which the cumulative volume on a cumulative curve, obtained by determining the particle size distribution by a laser diffraction/scattering method, is 50%, the entire volume of the particles being set to 100%.

In the present disclosure, the “10% particle diameter d10” (hereinafter, also simply referred to as “d10”) is a volume-based cumulative 10% diameter of the particles determined using a laser diffraction particle size distribution measuring device (e.g., “MT3300EXII” manufactured by MicrotracBEL Corp.). In other words, it is a particle diameter at which the cumulative volume on a cumulative curve obtained by determining the particle size distribution by a laser diffraction/scattering method is 10%, the entire volume of the particles being set to 100%.

In the present disclosure, the “specific surface area” is determined by the BET method based on the nitrogen adsorption method using a specific surface area/pore distribution measuring device (e.g., “Tristar II” manufactured by Micromeritics Instrument Corporation).

In the present disclosure, the “sphericity” refers to an average value obtained by measuring the maximum diameter (DL) and the minor axis (DS) perpendicular to the maximum diameter (DL) of each of 100 random particles in a photographic projection obtained by photographing the particles with a scanning electron microscope (SEM) and calculating the ratio (DS/DL) of the minor axis (DS) to the maximum diameter (DL).

In the present disclosure, the “dielectric tangent” and “dielectric constant” are measured by a perturbation resonator method using a dedicated device (e.g., the “Vector Network Analyzer E5063A” manufactured by KEYCOM Corporation).

In the present disclosure, the “viscosity” refers to a viscosity at 30 seconds measured at 25° C. for 30 seconds using a rotational rheometer (e.g., Modular Rheometer Physica MCR-301 manufactured by Anton Paar) at a shear rate of 1 rpm.

In the present disclosure, the “thixotropy ratio” is calculated by dividing the viscosity measured at a rotation speed of 1 rpm by the viscosity measured at a rotation speed of 60 rpm using a rotational rheometer.

In the present disclosure, the “weight average molecular weight” is determined using gel permeation chromatography (GPC) in terms of polystyrene.

In the present disclosure, the “surface tension” is measured by the Wilhelmy method using a surface tensiometer for a solvent at 25° C.

In the present disclosure, the “boiling point” is a boiling point at a normal pressure of 1.013×10⁵ Pa.

In the present disclosure, the “evaporation rate” based on butyl acetate is a relative evaporation rate when the evaporation rate of butyl acetate at 23° C. is set to 1.

In the present disclosure, the “liquid composition” refers to a composition that is liquid at 25° C.

In the present disclosure, the “semi-cured product” refers to a cured product of a liquid composition in a state in which an exothermic peak associated with curing of a thermosetting resin appears when the cured product of the liquid composition is measured by differential scanning calorimetry. In other words, the “semi-cured product” refers to a cured product in which an uncured thermosetting resin remains.

In the present disclosure, the “cured product” refers to a cured product of a liquid composition in a state in which an exothermic peak associated with curing of a thermosetting resin does not appear when the cured product of the liquid composition is measured by differential scanning calorimetry. In other words, the “cured product” refers to a cured product in which an uncured thermosetting resin does not remain.

In the present disclosure, the maximum height roughness Rz is measured in accordance with JIS B 0601 (2013).

In the description of the silica particles contained in the liquid composition according to the present disclosure, when “silica particles” are simply referred to without specifying whether the description is in relation to the “first silica particles” or the “second silica particles”, the description is a comprehensive description of the first and second silica particles.

The liquid composition according to the present disclosure (hereinafter also referred to as “present composition”) contains a thermosetting resin, first silica particles, second silica particles, and a solvent, wherein the first silica particles have a d50 of from 1.5 μm to 20.0 μm, the product of the specific surface area and the d50 being from 2.7 to 5.0 μm m²/g, and the second silica particles have a d50 of from 0.3 μm to less than 1.5 μm.

It has been found that the present composition can suppress the aggregation of silica particles. Although the reason for this is not entirely clear, it is presumed as follows.

The inventor has found that the more spherical and denser silica particles having a d50 of from 1.5 μm to 20.0 μm, in which the product of the specific surface area and the d50 is from 2.7 to 5.0 μm·m²/g, have excellent ease of mixing with resin components. Furthermore, the inventor has found that, when such silica particles are combined with silica particles having a smaller d50, their aggregation in the liquid composition is also effectively suppressed.

It is believed that, in the liquid composition according to the present disclosure, the first silica particles, which have a relatively large d50, are highly wetted and stabilized in the liquid composition, thereby interacting with the thermosetting resin as well as interacting with the second silica particles to improve their wettability and dispersion, whereby the thixotropy of the liquid composition is improved. It has been found that such an effect is particularly exhibited when the filling rate of the silica particles is high. It is believed that, when a shaped material is formed from the liquid composition in such a state, aggregation and segregation of the silica particles in the shaped material are suppressed. It is believed that this improves the film density when a shaped material is formed, suppresses surface roughness, and enables the properties of silica particles to be fully exhibited.

The present composition contains a thermosetting resin. One type of thermosetting resin may be used singly, or two or more types thereof may be used in combination. Examples of the thermosetting resin include an epoxy resin, a polyphenylene ether resin, a polyimide resin, a phenol resin, and an ortho-divinylbenzene resin. From the viewpoint of adhesion, heat resistance, and the like, the thermosetting resin is preferably an epoxy resin, a polyphenylene ether resin, or an ortho-divinylbenzene resin.

Examples of the epoxy resin include a bisphenol A-type epoxy resin, a bisphenol F-type epoxy resin, a bisphenol S-type epoxy resin, an alicyclic epoxy resin, a phenol novolac-type epoxy resin, a cresol novolac-type epoxy resin, a bisphenol A novolac-type epoxy resin, a diglycidyl-etherified product of a polyfunctional phenol, and a diglycidyl-etherified product of a polyfunctional alcohol.

The polyphenylene ether resin may be either a modified polyphenylene ether or an unmodified polyphenylene ether. From the viewpoint of adhesion, a modified polyphenylene ether is preferred. The modified polyphenylene ether has a substituent bonded to a polyphenylene ether chain or an end of the polyphenylen ether chain. The substituent is preferably a group having a reactive group, and more preferably a group having a vinyl group, a (meth)acryloyloxy group, or an epoxy group.

A hydrogen atom of a phenylene group in the polyphenylene ether chain may be substituted with an alkyl group, an alkenyl group, an alkynyl group, a formyl group, an alkylcarbonyl group, an alkenylcarbonyl group, or an alkynylcarbonyl group.

From the viewpoint of adhesion, dielectric properties, and the like, the weight average molecular weight of the polyphenylene ether resin is preferably from 1,000 to 7,000, more preferably from 1,000 to 5,000, and still more preferably from 1,000 to 3,000.

From the viewpoint of adhesion and the like, the content of the thermosetting resin with respect to the total mass of the present composition is preferably from 10% to 40% by mass, more preferably from 15% to 35% by mass, and still more preferably from 20% to 30% by mass.

The present composition contains first silica particles and second silica particles. The first silica particles have a d50 of from 1.5 μm to 20.0 μm, and the product of the specific surface area and the d50 is from 2.7 to 5.0 μm m²/g. The second silica particles have a d50 of from 0.3 μm to less than 1.5 μm.

The d50 of the first silica particles is from 1.5 μm to 20.0 μm. From the viewpoint of suppressing the aggregation of the silica particles more favorably, the d50 of the first silica particles is more preferably from 1.5 μm to 10.0 μm, and still more preferably from 1.5 μm to 5.0 μm.

From the viewpoint of suppressing the aggregation of the silica particles more favorably, the d10 of the first silica particles is preferably from 0.2 μm to 10.0 μm, more preferably from 0.5 μm to 5.0 μm, and still more preferably from 1.0 μm to 2.5 μm.

From the viewpoint of suppressing the aggregation of the silica particles more favorably, the ratio of d50 to d10 (d50/d10) of the first silica particles is preferably from greater than 1.0 to 5.0, more preferably from 1.1 to 4.0, still more preferably from 1.2 to 2.4, and particularly preferably from 1.3 to 2.2.

From the viewpoint of suppressing the aggregation of the silica particles more favorably, the specific surface area of the first silica particles is preferably from 0.1 to 3.5 m²/g, more preferably from 0.3 to 3.0 m²/g, and still more preferably from 0.8 to 2.0 m²/g.

The product of the specific surface area and the d50 of the first silica particles is from 2.7 to 5.0 μm·m²/g. From the viewpoint of suppressing the aggregation of the silica particles more favorably, the product is preferably from 2.7 to 4.5 μm·m²/g, more preferably from 2.7 to 4.3 μm·m²/g, and still more preferably from 3.0 to 4.1 μm·m²/g.

The d50 of the second silica particles is from 0.3 μm to less than 1.5 am. From the viewpoint of suppressing the aggregation of the silica particles more favorably, it is more preferably from 0.4 μm to 1.2 am, and still more preferably from 0.5 μm to 1.0 am.

From the viewpoint of suppressing the aggregation of the silica particles more favorably, the mass ratio of the first silica particles to the second silica particles (first silica particles/second silica particles) is preferably from 0.1 to 10.0, more preferably from 0.5 to 8.0, and still more preferably from 1.0 to 5.0. Even when the mass ratio is small, in other words, even when it is considered that the number of the second silica particles is large, the aggregation and segregation of the silica particles in a shaped material formed from the present composition are suppressed owing to the above-described mechanism of action, which tends to result in a balanced and improved film density and surface roughness of the shaped material.

The d50 of the first silica particles is preferably in a range of from 2.0 to 8.0 times larger, more preferably in a range of from 2.5 to 7.0 times larger, and still more preferably in a range of from 3.0 to 6.0 times larger, than the d50 of the second silica particles.

The silica particles in the present composition preferably have two peaks, including a peak formed by the first silica particles and a peak formed by the second silica particles, in a particle size distribution obtained by a laser diffraction/scattering method. In other words, it is preferable that the silica particles in the present composition are bimodal. It is believed that the presence of a higher particle diameter peak arising from the first silica particles and a lower particle diameter peak arising from the second silica particles enhances the dispersion of the silica particles in the present composition, thereby enabling more favorable suppression of the aggregation.

When the silica particles in the present composition are bimodal, each of the peaks is preferably adjusted to be within the ranges set forth above as preferred ranges of d50 of the first silica particles and preferred ranges of d50 of the second silica particles, respectively.

The shape of each silica particle of the silica particles is preferably spherical from the viewpoint of achieving a high level of balance between the physical properties of the present composition itself, such as dispersion stability and flowability, and the physical properties of a shaped material formed from the present composition, such as adhesion and low dielectric tangent. From the same viewpoint, the sphericity of the spherical silica particles is preferably 0.75 or more, more preferably 0.90 or more, still more preferably 0.93 or more, and particularly preferably 1.00. Further, from the same viewpoint, the silica particles are preferably non-porous particles.

From the viewpoint of reducing transmission loss in a circuit, the dielectric tangent of the silica particles is preferably 0.0020 or less, more preferably 0.0010 or less, and still more preferably 0.0008 or less, at a frequency of 1 GHz.

From the same viewpoint, the dielectric constant of the silica particles is preferably 5.0 or less, more preferably 4.5 or less, and still more preferably 4.1 or less, at a frequency of 1 GHz.

Each silica particle may be treated with a silane coupling agent. By treating the surface of the silica particles with a silane coupling agent, the amount of remaining silanol groups on the surface is reduced, the surface is hydrophobized, and moisture adsorption is suppressed, whereby the dielectric loss is improved. It also enhances the affinity with the thermosetting resin in the present composition, and improves dispersion and strength after resin film formation.

Examples of the silane coupling agent include an aminosilane-based coupling agent, an epoxysilane-based coupling agent, a mercaptosilane-based coupling agent, a silane-based coupling agents, and an organosilazane compound. One type of silane coupling agents may be used singly, or two or more types thereof may be used in combination.

The amount of the silane coupling agent attached is preferably from 0.01 to 5 parts by mass, and more preferably 0.10 to 2 parts by mass, with respect to 100 parts by mass of the silica particles.

The fact that the surface of the silica particles has been treated with a silane coupling agent can be confirmed by detecting a peak of a substituent of the silane coupling agent by IR.

The amount of the silane coupling agent attached can be measured based on the amount of carbon.

The silica particles contain preferably from 30 to 1500 ppm by mass, more preferably from 100 to 1000 ppm by mass, and still more preferably from 100 to 500 ppm by mass, of titanium (Ti). Ti is a component that is optionally included in the production of the silica particles. During the production of the silica particles, generation of fine powder due to cracking of the silica particles increases the specific surface area of the particles. By adding Ti during the production of the silica particles, the particles can be easily compacted by heat during firing, and the cracking of the particles can be suppressed. As a result, the generation of fine powder can be suppressed, and the amount of particles attached to the surface of the base particles of the silica particles can be reduced, making it easier to adjust the specific surface area of the silica particles. By including 30 ppm by mass or more of Ti, the silica particles are easily thermally compacted during the firing, and the generation of fine powder due to cracking can be suppressed. When the Ti content is 1,500 ppm by mass or less, in addition to obtaining the foregoing effect, increase in the amount of silanol groups can be suppressed, thereby lowering the dielectric tangent.

The silica particles may contain impurity elements other than titanium (Ti) as long as the effects of the present disclosure are not impaired. Examples of the impurity elements other than Ti include Na, K, Mg, Ca, Al, and Fe. The total content of alkali metals and alkaline earth metals among the impurity elements is preferably 2000 ppm by mass or less, more preferably 1000 ppm by mass or less, and still more preferably 200 ppm by mass or less.

The silica particles are preferably silica particles produced by a wet method. The wet method refers to a technique that involves a process of gelling a liquid silica source to obtain a raw material for the silica particles. By using the wet method, the shape of the silica particles tends to be easily adjusted, and in particular, spherical silica particles tend to be easily prepared. Therefore, it is not necessary to adjust the particle shape by crushing or the like, and as a result, particles with a small specific surface area tend to be easily obtained. Further, in the wet method, particles that are significantly smaller than the average particle diameter are less likely to be generated, and the specific surface area after the firing tends to be small. In addition, in the wet method, the amount of impurity elements, such as titanium, can be adjusted by adjusting the impurities in the silica source, and further, the above-described impurity elements can be uniformly dispersed in the particles.

Examples of the wet method include a spray method and an emulsion-gelation method. In the emulsion-gelation method, for example, a continuous phase and a dispersed phase containing a silica precursor are emulsified, and the resulting emulsion is gelled to obtain a spherical silica precursor. A preferred emulsification method is a method in which a dispersed phase containing a silica precursor is added to a continuous phase through a microporous portion or a porous membrane, thereby preparing an emulsion. This allows the production of an emulsion having a uniform droplet size, resulting in spherical silica particles having a uniform particle diameter. Examples of such an emulsification method include a micromixer method and a membrane emulsification method. For example, the micromixer method is disclosed in WO2013/062105.

The silica particles can be obtained by heat-treating the silica precursor. The heat treatment has an effect of sintering the spherical silica precursor to densify the shell, as well as reducing the amount of silanol groups on the surface to lower the dielectric tangent. The temperature of the heat treatment is preferably 700° C. or more. From the viewpoint of suppressing the aggregation of the particles, the temperature of the heat treatment is preferably 1600° C. or less. Further, the obtained silica particles may be surface-treated with a silane coupling agent.

From the viewpoint of suppressing the aggregation of the silica particles, reducing water absorption, low dielectric tangent, adhesion, and the like, the total content of the silica particles with respect to the total solid content of the liquid composition is preferably from 10% to 90% by mass, more preferably from 30% to 85% by mass, and still more preferably from 40% to 80% by mass. Even when the total content of the silica particles is high, which tends to result in a reduced flowability of the composition, the aggregation and segregation of the silica particles in a shaped material formed from the present composition are suppressed owing to the above-described mechanism of action, which tends to result in a balanced and improved film density and surface roughness of the shaped material. In particular, when a high filling rate of the silica particles is desired, the total content of the silica particles is preferably 50% by mass or more, more preferably 60% by mass or more, and still more preferably 70% by mass or more. In this case, the total content of the silica particles may be 95% by mass or less, or may be 90% by mass or less.

From the viewpoint of suppressing the aggregation of the silica particles, reducing water absorption, low dielectric tangent, adhesion, and the like, the amount of the silica particles with respect to 100 parts by mass of the thermosetting resin is preferably from 10 to 600 parts by mass, more preferably from 50 to 550 parts by mass, and still more preferably from 70 to 500 parts by mass. In particular, when a high filling rate of the silica particles is desired, the amount of the silica particles is preferably 300 parts by mass or more, and more preferably 400 parts by mass or more.

The present composition may include one or more kinds of solvents. Examples of the solvent include acetone, methanol, ethanol, butanol, 2-propanol, 2-methoxyethanol, 2-ethoxyethanol, toluene, xylene, methyl ethyl ketone, N,N-dimethylformamide, methyl isobutyl ketone, N-methyl-2-pyrrolidone, n-hexane, and cyclohexane. From the viewpoint of adhesion or the like, the solvent preferably includes at least one selected from the group consisting of toluene, cyclohexanone, methyl ethyl ketone, and N-methyl-2-pyrrolidone. The content of the solvent with respect to the total mass of the present composition is not particularly limited, and may be, for example, from 10% to 60% by mass.

From the viewpoint of suppressing the aggregation of the silica particles and the like, the surface tension of the solvent is preferably 40 mN/m or less, more preferably 35 mN/m or less, and still more preferably 30 mN/m or less. The lower limit of the surface tension is not particularly limited, and may be, for example, 5 mN/m.

From the viewpoint of suppressing the aggregation of silica particles, the boiling point of the solvent is preferably 75° C. or higher, more preferably 80° C. or higher, and still more preferably 90° C. or higher. The upper limit of the boiling point is not particularly limited, and may be 200° C. or less.

From the viewpoint of suppressing the aggregation of the silica particles, the evaporation rate of the solvent is preferably from 0.3 to 3.0, and more preferably from 0.4 to 2.0, when the evaporation rate of butyl acetate is set to 1.

The present composition may contain one or more kinds of curing agents. A curing agent is an agent that initiates a curing reaction of a thermosetting resin by the action of heat. Specific examples thereof include α,α′-bis(t-butylperoxy-m-isopropyl)benzene, 2,5-dimethyl-2,5-di(t-butylperoxy)-3-hexyne, benzoyl peroxide, 3,3′,5,5′-tetramethyl-1,4-diphenoquinone, chloranil, 2,4,6-tri-t-butylphenoxyl, t-butylperoxyisopropyl monocarbonate, and azobisisobutyronitrile. The amount of the curing agent with respect to 100 parts by mass of the thermosetting resin is preferably from 0.1 to 5 parts by mass.

The present composition may contain one or more kinds of curing accelerators. Examples of the curing accelerator include: a triaryl isocyanurate compound, such as triallyl isocyanurate; a polyfunctional acrylic compounds having two or more acryloyl or methacryloyl groups in the molecule; a polyfunctional vinyl compound having two or more vinyl groups in the molecule; and a vinylbenzyl compound having a vinylbenzyl group in the molecule, such as styrene. The amount of the curing accelerator with respect to 100 parts by mass of the thermosetting resin is preferably from 10 to 100 parts by mass.

The present composition may contain one or more plasticizers. Examples of the plasticizer include a butadiene-styrene copolymer. The amount of the plasticizer with respect to 100 parts by mass of the thermosetting resin is preferably from 10 to 50 parts by mass, and more preferably from 20 to 40 parts by mass.

The present composition may further contain other component(s), in addition to the above-described components, such as a surfactant, a thixotropic agent, a pH adjuster, a pH buffer, a viscosity regulator, a defoamer, a silane coupling agent, a dehydrating agent, a weathering agent, an antioxidant, a heat stabilizer, a lubricant, an antistatic agent, a brightener, a colorant, a conductive material, a release agent, a surface treatment agent, a flame retardant, or various organic or inorganic fillers, as long as the effects of the composition are not impaired.

From the viewpoint of suppressing the aggregation of the silica particles more favorably, the viscosity of the present composition measured at a rotation speed of 1 rpm at 25° C. is preferably from 100 to 10000 mPa·s, more preferably from 130 to 5000 mPa·s, still more preferably from 150 to 3000 mPa·s, particularly preferably from 180 to 1500 mPa·s, and most preferably from 200 to 1000 mPa·s.

From the viewpoint of suppressing the aggregation of the silica particles more favorably, the thixotropy ratio of the present composition is preferably 3.0 or less, more preferably 2.5 or less, and still more preferably 2.0 or less. The lower limit of the thixotropy ratio is not particularly limited, and may be 0.5 or more.

A prepreg according to the present disclosure includes: the present composition or a semi-cured product thereof; and a fibrous substrate. Examples of the fibrous substrate include glass cloth, aramid cloth, polyester cloth, glass nonwoven fabric, aramid nonwoven fabric, polyester nonwoven fabric, and pulp paper. The thickness of the fibrous substrate is not particularly limited, and may be from 3 μm to 10 μm. Since the present composition is described above, the description thereof will be omitted here.

The prepreg according to the present disclosure can be produced by coating or impregnating the fibrous substrate with the present composition. After the application or impregnation with the present composition, the liquid composition may be heated to be semi-cured.

The metal substrate with a resin according to the present disclosure includes: the present composition or a semi-cured product thereof or the above-described prepreg; and a metal substrate layer. The metal substrate layer may be provided at the surface of one side or both sides of the present composition or the semi-cured product thereof or the above-described prepreg.

The type of the metal substrate layer is not particularly limited, and examples of the metal constituting the metal substrate layer include copper, a copper alloy, stainless steel, nickel, a nickel alloy (including alloy 42), aluminum, an aluminum alloy, titanium, and a titanium alloy. The metal substrate layer is preferably a metal foil, and more preferably a copper foil, such as a rolled copper foil or an electrolytic copper foil. The surface of the metal foil may be subjected to an anti-rust treatment (such as an oxide film of chromate or the like) or a roughening treatment. As the metal foil, a metal foil with a carrier, that has a carrier copper foil (thickness: from 10 to 35 μm) and an ultra-thin copper foil (thickness: from 2 to 5 μm) layered on the surface of the carrier copper foil via a release layer, may be used. The surface of the metal substrate layer may be treated with a silane coupling agent. In this case, the entire surface of the metal substrate layer may be treated with the silane coupling agent, or only a part of the surface of the metal substrate layer may be treated with the silane coupling agent. Those mentioned above may be used as the silane coupling agent.

The thickness of the metal substrate layer is preferably from 1 μm to 40 μm, and more preferably from 2 μm to 15 μm. From the viewpoint of reducing the transmission loss, the maximum height roughness (Rz) of the metal substrate layer is preferably 2 μm or less, and more preferably 1.2 μm or less.

In one embodiment, the metal substrate with a resin according to the present disclosure can be produced by coating the surface of a metal substrate layer with the present composition. After the coating of the present composition, the liquid composition may be heated to be semi-cured.

In another embodiment, the metal substrate with a resin according to the present disclosure can be produced by layering a metal substrate layer and a prepreg. Examples of the method of layering the metal substrate layer and the prepreg include a method of subjecting them to thermal compression bonding.

A wiring board according to the present disclosure includes a cured product of the present composition and a metal wiring. The metal wiring produced by, for example, etching the above-described metal substrate layer may be used.

The wiring board according to the present disclosure can be produced, for example, by a method of etching the metal substrate layer of the above-described metal substrate with a resin, or a method of forming a pattern circuit on the surface of a cured product of the present composition by electrolytic plating (semi-additive process (SAP process), modified semi-additive process (MSAP process), or the like).

### EXAMPLES

Hereinafter, embodiments of the present disclosure will be described in detail with reference to Examples. However, the embodiments of the present disclosure are not limited thereto.

### (Method of Measuring d50 of Silica Particles)

The d50 of the silica particles used in each of the Examples was measured by a laser diffraction/scattering method using a particle size distribution measuring device (MT3300EXII manufactured by MicrotracBEL Corp.). Specifically, the silica particles were dispersed in the device by irradiating them with ultrasonic waves three times for 60 seconds, and then the measurement was performed. The d50 was measured twice for 60 seconds each, and the average value was calculated. The d50s of the silica particles used in the Examples are summarized in Table 1.

### (Method of Measuring Specific Surface Area of Silica Particles)

The silica particles used in each of the Examples were dried at 230° C. under reduced pressure to remove the moisture completely, and were used as a sample. The specific surface area of the sample was determined by the multipoint BET method using nitrogen gas with an automatic specific surface area/pore distribution measuring device, Tristar II, manufactured by Micromeritics Instrument Corporation. The specific surface areas of the silica particles used in the Examples are summarized in Table 1.

### 1. Preparation of Components for Producing Liquid Composition

### [Thermosetting Resin]

Polyphenylene ether resin: Modified polyphenylene ether in which the terminal hydroxyl groups of polyphenylene ether are modified with methacrylic groups, Noryl SA9000 manufactured by SABIC; Mw: 1700; number of functional groups per molecule: 2

### [Silica Particles]

Silica particles A1: Silica particles A1 were obtained by filling an alumina crucible with 15 g of silica powder 1 (H-31 manufactured by AGC Si-Tech Co., Ltd.; d50: 3.5 μm) produced by a wet method as a spherical silica precursor, heat-treating the powder at a temperature of 1200° C. in an electric furnace for 1 hour, followed by cooling to room temperature (25° C.) and then crushing in an agate mortar.

Silica particles A2: Silica particles A2 were obtained by filling an alumina crucible with 15 g of silica powder 2 (E-2C manufactured by SUZUKIYUSHI INDUSTRIAL CORPORATION; d50=2.5 μm) produced by a wet method as a spherical silica precursor, heat-treating the powder at a temperature of 1200° C. in an electric furnace for 1 hour, followed by cooling to room temperature (25° C.) and then crushing in an agate mortar.

Silica particles B1: A spherical silica powder (SC-02 manufactured by Admatechs: d50: 0.6 μm) produced from a raw material silica produced by the vaporized metal combustion (VMC) method was used as it was.

### 2. Production of Liquid Composition and Cured Product

### Example 1

59 parts by mass of the polyphenylene ether resin, 16 parts by mass of a butadiene-styrene random copolymer (RICON 100 manufactured by Cray Valley), 25 parts by mass of triallyl isocyanurate (polymerization accelerator, TAIC manufactured by Mitsubishi Chemical Group Corporation), 1 part by mass of α,α′-di(t-butylperoxy)diisopropylbenzene (polymerization initiator, PERBUTYL (registered trademark) P, NOF CORPORATION), 208 parts by mass of silica particles A1 (first silica particles), 52 parts by mass of silica particles B1 (second silica particles), and 80 parts by mass of toluene were placed in a polyethylene bottle. Alumina balls having a diameter (<D) of 20 mm were added thereto and mixed at 30 rpm for 12 hours, and the alumina balls were then removed to obtain a varnish.

Next, a release-treated transparent polyethylene terephthalate (PET) film (“PET5011 550” manufactured by LINTEC Corporation; thickness: 50 μm) was prepared. The obtained varnish was applied to the release-treated surface of this PET film using an applicator such that the thickness after drying is 40 μm, and the film was dried and cured for 90 minutes in a gear oven at 190° C., thereby producing a cured resin film (evaluation sample) having dimensions of 200 mm in length×200 mm in width×40 μm in thickness.

### Examples 2 to 8

Liquid compositions and cured products were produced in the same manner as in Example 1, except that those shown in Table 1 were used as the first and second silica particles in the amounts shown in Table 1.

### [Measurement of Film Density]

The cured product was cut into a20 mm square, and the mass m (g) of the film obtained by subtracting the mass of the 20 mm-square copper foil was determined. The thickness L (cm) of the cured product was measured using a constant pressure thickness measuring device manufactured by TECLOCK Co., Ltd. The film density was calculated therefrom using the formula: film density (g/cm³)=2500*m/L.

### [Measurement of Rz]

The Rz of the cured product was measured in accordance with JIS B 0601 (2013). The measurement results are summarized in Table 1.

TABLE 1

| | Type of silica | | | | | | Amount of silica | | | | | |
|---|---|---|---|---|---|---|---|---|---|---|---|---|
| | particles | | | | | | particles | | | | | |
| | | | | | | | First | Second | | | | |
| | First silica particles | | | | | | silica | silica | | | Physical properties | |
| | | | Specific | | | | particles | particles | Total silica particles | | of cured product | |
| | | | surface | | Second silica particles | | Content | Content | Content | Content in | Film | |
| | | d50 | area | Product | | d50 | (parts by | (parts by | (parts by | composition | density | Rz |
| | Type | (μm) | (m²/g) | (μm · m²/g) | Type | (μm) | mass) | mass) | mass) | (% by mass) | (g/cm³) | (μm) |
| Example 1 | A1 | 3.0 | 1.0 | 3.0 | B1 | 0.6 | 208 | 52 | 260 | 70 | 1.7 | 0.5 |
| Example 2 | A2 | 2.0 | 2.2 | 4.4 | B1 | 0.6 | 208 | 52 | 260 | 70 | 1.7 | 0.2 |
| Example 3 | A1 | 3.0 | 1.0 | 3.0 | — | — | 260 | 0 | 260 | 70 | 0.3 | 3.5 |
| Example 4 | — | — | — | — | B1 | 0.6 | 0 | 260 | 260 | 70 | 1.2 | 3.0 |
| Example 5 | A1 | 3.0 | 1.0 | 3.0 | B1 | 0.6 | 400 | 100 | 500 | 92 | 1.5 | 1.6 |
| Example 6 | A2 | 2.0 | 2.2 | 4.4 | B1 | 0.6 | 125 | 135 | 260 | 70 | 1.4 | 0.7 |
| Example 7 | A2 | 2.0 | 2.2 | 4.4 | B1 | 0.6 | 220 | 40 | 260 | 70 | 1.5 | 0.9 |
| Example 8 | A1 | 3.0 | 1.0 | 3.0 | B1 | 0.6 | 208 | 52 | 135 | 35 | 1.3 | 0.4 |

In Table 1, the “Product” represents a product of the specific surface area and d50, and “-” represents that the component is not included. The “Content in composition” refers to the total content (% by mass) of the silica particles with respect to the total solid content of the composition. As shown in Table 1, the cured products obtained using the present composition has a high film density and a low Rz, and the aggregation of the silica particles is highly suppressed.

The disclosure of Japanese Patent Application No. 2022-065666 filed on Apr. 12, 2022 is incorporated herein by reference in its entirety. All publications, patent applications, and technical standards mentioned herein are incorporated herein by reference to the same extent as if each publication, patent application, and technical standard was specifically and individually indicated to be incorporated by reference.

1. A liquid composition, comprising:
a thermosetting resin;
first silica particles;
second silica particles; and
a solvent, wherein:
the first silica particles have a median diameter d50 of from 1.5 μm to 20.0 μm, a product of a specific surface area of the first silica particles and the median diameter d50 being from 2.7 to 5.0 μm m²/g; and
the second silica particles have a median diameter d50 of from 0.3 μm to less than 1.5 μm.

2. The liquid composition according to claim 1, wherein a total content of silica particles is from 10% to 90% by mass based on a total solid content of the liquid composition.

3. The liquid composition according to claim 1, wherein a mass ratio of the first silica particles to the second silica particles (first silica particles/second silica particles) is from 0.1 to 10.0.

4. The liquid composition according to claim 1, wherein the median diameter d50 of the first silica particles is in a range of from 2.0 to 8.0 times larger than the median diameter d50 of the second silica particles.

5. The liquid composition according to claim 1, wherein the first silica particles have a specific surface area of from 0.1 to 3.5 m²/g.

6. The liquid composition according to claim 1, wherein the first silica particles have a median diameter d50 of from 1.5 μm to 5.0 μm.

7. The liquid composition according to claim 1, wherein silica particles in the liquid composition exhibit a bimodal particle size distribution as measured by a laser diffraction/scattering method.

8. The liquid composition according to claim 1, wherein the thermosetting resin is at least one selected from the group consisting of an epoxy resin, a polyphenylene ether resin, and an ortho-divinylbenzene resin.

9. The liquid composition according to claim 1, wherein the solvent comprises at least one selected from the group consisting of toluene, cyclohexanone, methyl ethyl ketone, and N-methyl-2-pyrrolidone.

10. A prepreg, comprising:
the liquid composition according to claim 1 or a semi-cured product thereof; and
a fibrous substrate.

11. A metal substrate with a resin comprising:
the liquid composition according to claim 1 or a semi-cured product thereof; and
a metal substrate layer.

12. A metal substrate with a resin comprising:
the prepreg according to claim 10; and
a metal substrate layer.

13. The metal substrate with a resin according to claim 11, wherein the metal substrate layer comprises a copper foil.

14. The metal substrate with a resin according to claim 13, wherein the copper foil has a maximum height roughness Rz of 2 μm or less.

15. A wiring board, comprising:
a cured product of the liquid composition according to claim 1; and
a metal wiring.
